(19) United States
(12) Patent Application Publication
(10) Pub. No.: US 2009/0010071 A1
(43) Pub. Date: Jan. 8, 2009

(54) NONVOLATILE MEMORY DEVICE AND ERASING METHOD

(75) Inventor: Seung-Won LEE, Seongnam-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/164,226

(22) Filed: Jun. 30, 2008

(30) Foreign Application Priority Data
Jul. 2, 2007 (KR) 10-2007-0066149

(51) Int. Cl. G11C 16/16

(52) U.S. Cl. 365/185.22; 365/185.29

(57) ABSTRACT

Disclosed is an erasing method for a nonvolatile memory device that includes erasing selected memory cells and erase-verifying the selected memory cells after increasing their threshold voltage by application of a negative bulk bias voltage.

### CROSS-REFERENCE TO RELATED APPLICATIONS

This U.S. non-provisional patent application claims priority under 35 U.S.C. §119 to Korean Patent Application No. 10-2007-0066149 filed on Jul. 2, 2007, the subject matter of which is hereby incorporated by reference.

### BACKGROUND

The present invention relates generally to nonvolatile memory devices. More particularly, the present invention relates to a flash memory device and a method of erasing memory cells in same.

Semiconductor memories are widely used as essential microelectronic components in a variety of applications. The development of semiconductor memories is one characterized by continuing efforts to improve overall performance (i.e., data access speeds, reliability, etc.) while also increasing memory cell integration (i.e., increasing data storage capacity per unit of chip area).

Semiconductor memories may be classified as volatile and nonvolatile in their operative nature. In volatile memories, data is stored by defining a logic state for a bi-stable flip-flop circuit as in a static random access memory or by charging a capacitive element in a dynamic random access memory. But volatile memories lose stored data when power is interrupted.

In contrast, nonvolatile memories, such as mask ROMs (MROMs), programmable ROMs (PROMs), electrically programmable PROMs (EPROMs), and electrically erasable and programmable ROMs (EEPROMs), are able to retain stored data when power is interrupted. Depending on device type, data storage in a nonvolatile memory may be one-time write (i.e., permanent) or reprogrammable. Nonvolatile memories may be effectively used to store program files and micro-codes widely used in a variety of applications.

In one example, nonvolatile RAMs (nvRAMs) are commonly used in systems requiring frequent and fast data access exhibiting the best characteristics of conventional volatile and nonvolatile operation, or requiring reprogrammable nonvolatile operation. In other examples, various memory architecture types have been proposed that include additional logic circuits designed to further optimize functions associated with certain application specific requirements.

Certain nonvolatile memories, such as MROM, PROM, and EPROM, are difficult to reprogram due to inherent limitations in their erase and write functions. In contrast, EEPROM may be electrically erased and programmed. Accordingly, the EEPROM is widely used for system programming requiring continuous data updates, and auxiliary storage operations. Flash EEPROMs (hereinafter, referred to as ‘flash memory) may be fabricated with high integration density making it ideal for use in large-capacity auxiliary storage units. Flash memory generally includes NAND flash memory and NOR flash memory, where NAND flash memory enjoys greater integration density.

As is conventionally understood, flash memory comprises a memory cell array including pluralities of defined memory blocks. Each memory block is independently operable during read, erase, and program operations. Within this operating context, the time required to erase a memory block (or a plurality of memory blocks) is one factor defining the overall performance of a system including flash memory. Many approaches have been proposed for reducing memory block erase time. For example, techniques for erasing two or more memory blocks at the same time are disclosed in U.S. Pat. Nos. 5,841,721 and 5,999,446, the subject matter of which is hereby incorporated by reference.

Generally speaking, after simultaneously erasing memory blocks, it is necessary for flash memory to conduct an erase-verify operation to determine whether the memory blocks have been successfully erased. Such erase-verify operations must typically be conducted for each respective memory block that was erased. Thus, the address information associated with erased memory blocks must be retained by the flash memory and used during the subsequent erase-verify operation.

### SUMMARY

Embodiments of the invention provide nonvolatile memories capable of screening memory cells that have been weakly erased, and an erasing method for such nonvolatile memories.

In one embodiment, the invention provides an erasing method for a nonvolatile memory device, the method including, erasing selected memory cells, and erase-verifying the selected memory cells under a bias condition that increases the threshold voltage of the selected memory cells.

In another embodiment, the invention provides an erase-testing method for a nonvolatile memory device, the method including; erasing selected memory cells, erase-verifying the selected memory cells under a bias condition that increases the threshold voltage of the selected memory cells, identifying a number of failed word lines in the selected memory block in accordance with the erase-verifying of the selected memory cells, and repairing one or more of the failed word lines, if the number of failed word lines exceeds a reference value.

In another embodiment, the invention provides a nonvolatile memory device including; a plurality of nonvolatile memory cells arranged in a matrix of word lines and bit lines, a voltage generator configured to generate a word-line erase-verifying voltage applied to the word lines, and a bulk erase-verifying voltage applied to a bulk in which the plurality of memory cells is fabricated, a page buffer circuit configured to sense erased states for selected memory cells within the plurality of memory cells through the bit lines during an erase-verify operation, and a control logic block configured to control an erase operation, control the voltage generator such that the bulk erase-verifying voltage is a negative voltage increasing the threshold voltage of the selected memory cells during the erase-verify operation, and to determine whether the selected memory cells have been successfully erased in relation to the erased states of the selected memory cells as sensed by the page buffer circuit following the erase-verify operation.

### BRIEF DESCRIPTION OF THE FIGURES

FIG. 1 is a block diagram of a nonvolatile memory device according to an embodiment of the invention;

FIG. 2 is a waveform diagram showing bias conditions for an erase-verify operation according to an embodiment of the invention;

FIG. 3 is a sectional diagram of the string taken along line A-A′ of FIG. 1, and further illustrates the bias conditions for an erase-verify operation according to an embodiment of the invention;

FIG. 4 is an equivalent circuit diagram for a memory cell illustrating how to increase a threshold voltage by a negative voltage applied to a bulk;

FIG. 5 is a graph showing the change in a threshold-voltage distribution corresponding to an erased state in accordance with the application of a voltage to the bulk;

FIG. 6 is a general block diagram of a memory system according to an embodiment of the invention;

FIG. 7 is a flow chart summarizing a method of erasing stored data in an embodiment according to the invention;

FIG. 8 is a collection of waveform diagrams illustrating other bias conditions for an erase-verify operation according to an embodiment of the invention;

FIG. 9 is a sectional diagram of the string taken along line A-A′ of FIG. 1, and further illustrates the bias conditions of FIG. 8;

FIG. 10 is a flow chart summarizing another erasing method according to an embodiment of the invention;

FIG. 11 is a block diagram of a test system according to an embodiment of the invention;

FIG. 12 is a flow chart summarizing an erase-testing procedure associated with an erase-verify operation according to an embodiment of the invention; and

FIG. 13 is a block diagram of a computational logic system including a nonvolatile memory device according to an embodiment of the invention.

### DETAILED DESCRIPTION OF EMBODIMENTS

Embodiments of the invention will now be described with reference to the accompanying drawings. The present invention may, however, be embodied in different forms and should not be constructed as being limited to only the illustrated embodiments. Rather, the embodiments are presented as teaching examples. Throughout the specification, like reference numerals refer to like or similar elements.

In certain embodiments, a nonvolatile memory according to the present invention executes an erase-verify operation by raising threshold voltages applied to memory cells being erased to a predetermined level. For instance, the nonvolatile memory device may conduct the erase-verify operation under a voltage bias condition that includes increasing one or more threshold voltage(s) by applying a negative voltage to the semiconductor bulk in which the memory cells are formed. Under this condition, a nonvolatile memory according to an embodiment of the invention is able to screen weak-erased memory cells.

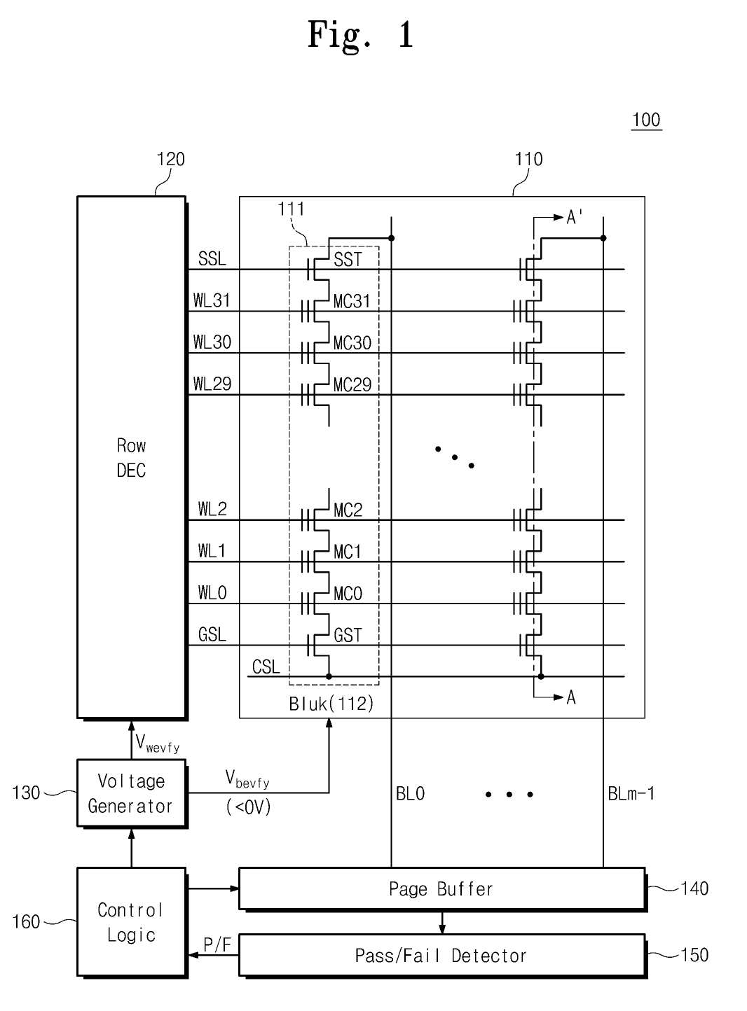

Figure (FIG.) 1 is a block diagram of a nonvolatile memory according to an embodiment of the invention. The exemplary nonvolatile memory device shown in FIG. 1 is a NAND flash memory, but the teachings of the present invention may just as readily be applied to other types of nonvolatile memories, including MROM, PROM, ferroelectric RAM (FRAM), and so forth.

Referring to FIG. 1, a nonvolatile memory device 100 comprises a memory cell array 110, a row decoder 120, a voltage generator 130, a page buffer circuit 140, a pass/fail detection circuit 150, and a control logic block 160. Nonvolatile memory device 100 is further configured to receive a negative voltage applied to the semiconductor bulk of the memory cells (hereafter, “the bulk”) during erase-verify operation. By applying the negative voltage to the bulk, the respective threshold voltages of the memory cells are raised. In other words, the erase-verify operation is conducted under a bulk-bias condition that raises the threshold voltage of the memory cells being erased.

Memory cell array 110 comprises a plurality of nonvolatile memory cells arranged in the customary matrix of rows and columns and the plurality of memory cells is further organized into a plurality of memory blocks. FIG. 1 only illustrates one memory block as an example of many other memory blocks in memory array 110.

Referring to FIG. 1, each memory block of the memory cell array 110 includes pluralities of cell strings. For convenience of description, each string is defined as including 32 memory cells, but the actual number of memory cells included in a cell string is a matter of design choice. Cell string 111 includes plurality of floating gate transistors MC0˜MC31 associated with the string of memory cells. Floating gate transistors MC0˜MC31 are serially connected along the string between a string selection transistor SST and a ground selection transistor GST. Multiple word lines WL0˜WL31 are arranged in rows to intersect the plurality columnar memory cell strings. Each word lines WL0˜WL31 is respectively coupled to the control gates of floating gate transistors MC0˜MC31 in each cell string 111. Certain control voltages associated with the programming, erasing, reading, or verifying of data are selectively applied to word lines WL0˜WL31 during program, read, erase, or verify operations directed to the memory cells. Each memory cell may store n-bit data, where n is a positive integer.

Row decoder 120 functions to decode a row address provided from a row address buffer (not shown) and select a word line according to a decoded result. The row address contains block information for selecting a memory block and page address information for designating pages (or word lines) of the selected memory block. Row decoder 120 is configured to store block address information of a memory block to be erased, by control logic block 160, in the erasing mode. Row decoder 120 drives the word lines of a selected memory block to word line voltages, which are generated from voltage generator 130 in accordance with an indicating mode of operation.

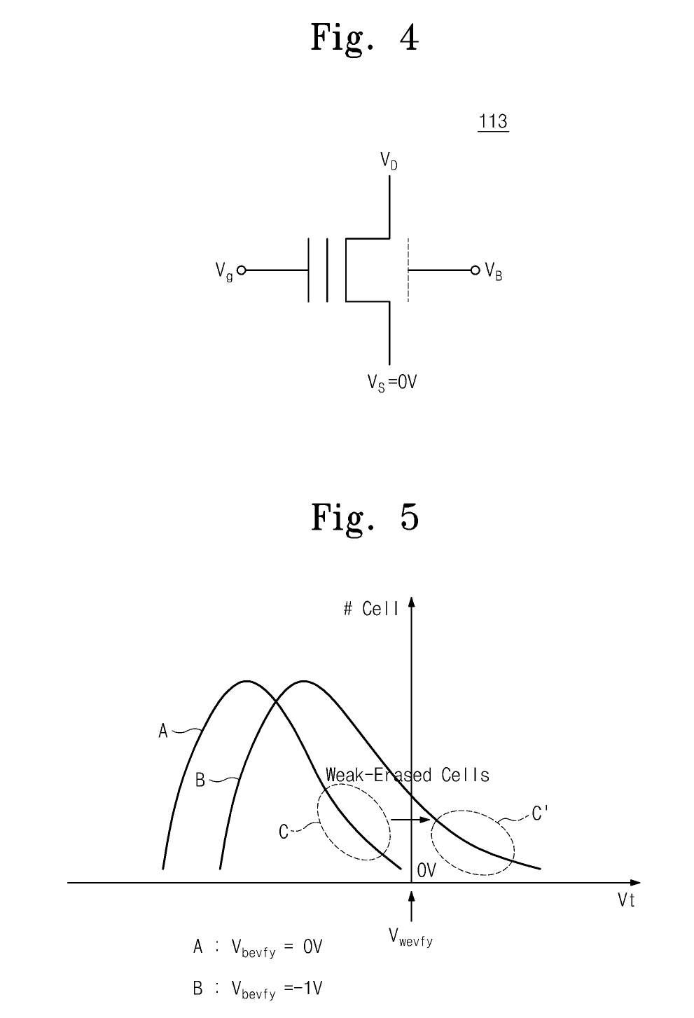

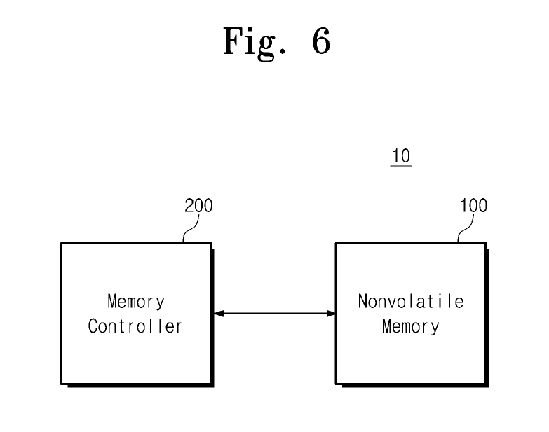

Voltage generator 130 generates the word line voltages to be supplied into the plurality of word lines, and the bulk voltage(s) to be supplied to the bulk, in accordance with an indicating mode of operation. For instance, the word line voltages may include a programming voltage, a passing voltage, a reading voltage, an erasing voltage, and an erase-verifying voltage. Voltage generator 130 may also be operated by a control logic block to generate a word-line (WL) erase-verifying voltage Vwevfy to be applied to the word lines, and a bulk erase-verifying voltage Vbevfy to be supplied to the bulk during an erase operation. Here, for the purpose of raising the threshold voltages of the memory cells, a negative voltage is used as the bulk erase-verifying voltage Vbevfy which will be detailed in some additional detail with reference to FIGS. 4 and 5.

Page buffer circuit 140 temporarily stores data which are detected from a selected page of memory cell array 110, or temporarily stores data (e.g., provided from a memory controller) to be programmed (hereinafter, referred to as ‘program data’) into a selected page. Page buffer circuit 140 is composed of a plurality of page buffers. Each page buffer functions as a sense amplifier or writing driver in accordance with an indicated mode of operation under control of the control logic block. Page buffer circuit 140 senses data from memory cell array 110 during a read or verify mode of operation. During an erase mode of operation, read data is output to an external circuit by an input/output circuit (not shown). Otherwise, data read during a verifying mode of operation is provided to pass/fail detection circuit 150.

As illustrated in the teaching example, page buffer circuit 140 is connected to multiple pluralities of bit lines BL0˜BLm-1. During a programming mode of operation, bit lines BL0˜BLm-1 are differentiated by program bit lines and program-inhibited bit lines in accordance with data latched in page buffer circuit 140. Here, the program bit lines are programmed with data ‘0’ while the program-inhibited bit lines are programmed with data ‘1’.

Pass/fail detection circuit 150 determines whether the data actually output from page buffer circuit 140 are identical to pass data obtained during a corresponding erase-verify operation. Pass/fail detection circuit 150 generates a pass/fail signal P/F and provides it to control logic block 160 as a result of program or an erase-verification operation.

Control logic block 160 operates to control the programming, reading, erasing, and verifying modes of operation. Control logic block 160 determines input timings of addresses, commands, and data in response to control signals CLE, ALE, CEB, REB, and WEB. Control logic block 160 controls the erasing mode to simultaneously erase the memory blocks corresponding to a block address in response to an erasing command. In the beginning of the erasing mode, control logic block 160 activates voltage generator 130 to generate the bulk voltage during the erasing mode. For instance, during the erasing mode, voltage generator 130 operates to generate a high voltage (e.g., 20V) to be applied to the bulk of a selected memory block under control by control logic block 160. Thus, the bulk voltage is provided to the bulk of the selected memory block.

Following the erasing mode, control logic block 160 initiates the erase-verify operation for the erased memory blocks in response to an erase-verifying command and block addresses input from external. Erase-verifying each memory block is carried out by the erase-verifying command and block address which are provided from external. Once the erase-verify operation begins, the control logic block 160 activates voltage generator 130 to generate the WL erase-verifying voltage Vwevfy and the bulk erase-verifying voltage Vbevfy for the erase-verify operation. In the illustrated embodiment, the bulk erase-verifying voltage Vbevfy is assumed to be negative. This negative voltage applied to the bulk of the erased memory block causes the threshold voltages of the erased memory cells to increase which will be discussed in some additional detail with reference to FIG. 4.

Meanwhile, the erase-verify operation according to an embodiment of the invention can be conducted with the same timing as the reading mode. Nonvolatile memory device 100 executes the erase-verify operation by applying the negative voltage to the bulk of the memory block. Thereby, it is able to screen weak-erased memory cells in the erase-verify operation which improves the overall reliability of the memory cells.

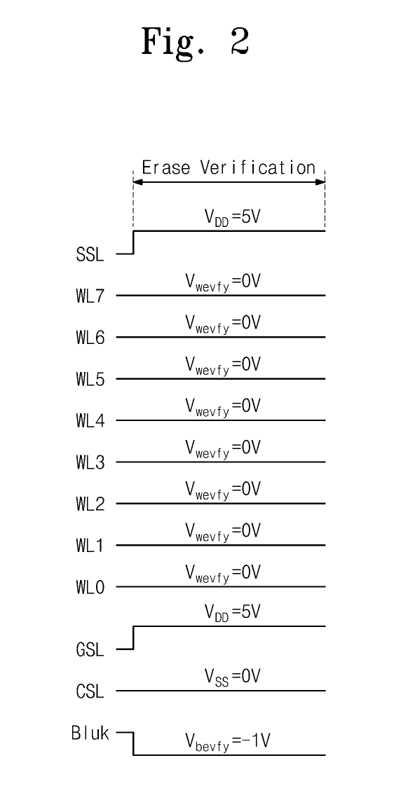

The erase-verify operation can be carried out in a memory block by memory block or a page by page mode of operation. This option will be described in some additional detail with reference to FIGS. 2 through 7.

FIG. 2 is a waveform diagram showing an exemplary bias condition for the erase-verify operation according to an embodiment of the invention. The erase-verify operation shown in FIG. 2 is conducted in a memory block unit size, for purposes of illustration. Referring to FIGS. 1 and 2, voltage generator 130 operates to generate the voltages necessary for the verifying mode under the control of control logic block 160. Responding to a block address, it selects a memory block in which the erase-verifying operation will be executed. The power source voltage VDD is applied to string and ground selection lines SSL and GSL of the selected memory block. The WL erase-verifying voltage Vwevfy is applied to the word lines WL0˜WL31. The ground voltage Vss is supplied to a common source line CSL and the bulk erase-verifying voltage Vbevfy is supplied to the bulk. Here, the bulk erase-verifying voltage Vbevfy is a negative voltage. In the particular embodiment of the invention illustrated in FIG. 2, the power source voltage VDD is 5V and the WL erase-verifying voltage Vwevfy is 0V and the bulk erase-verifying voltage Vbevfy is −1V.

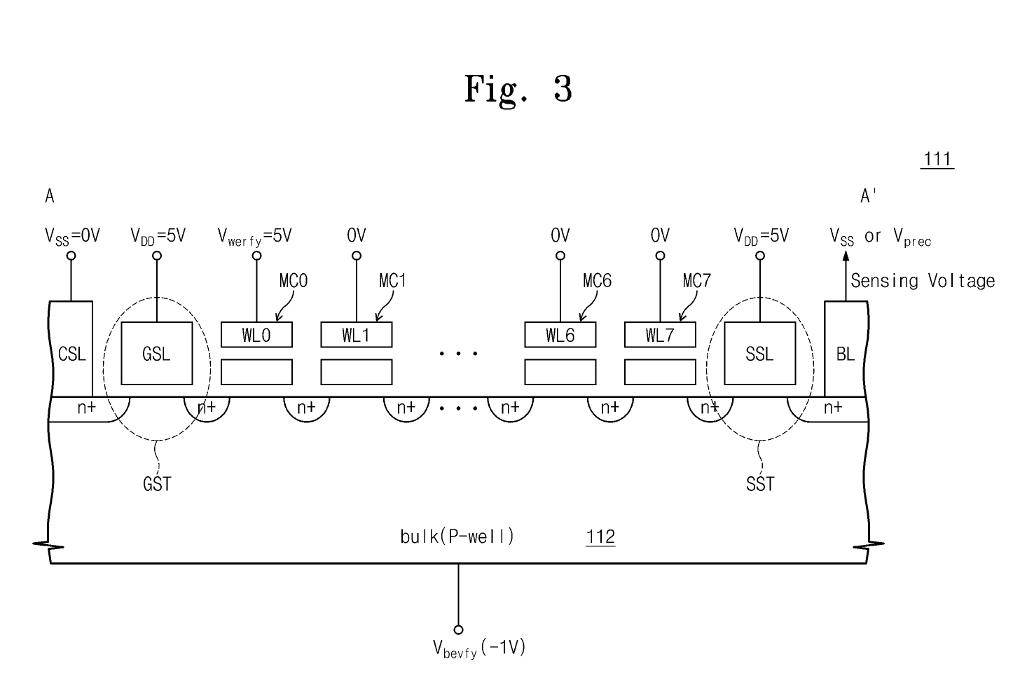

FIG. 3 is a sectional diagram of the string taken along the line A-A′ of FIG. 1, and structurally illustrates the bias condition for the erase-verify operation. Referring to FIG. 3, cell string 111 is formed in a semiconductor bulk 112. Bulk 112 shown in FIG. 3 is implemented in a P-well containing P-type impurities. Cell string 111 includes the common source line CSL, the ground selection line GSL, the memory cells MC0˜MC31, and the string selection line SSL, the bit line BL, and bulk 112. The ground selection transistor GST, the memory cells MC0˜MC31, and the string selection transistor SST are arranged between the common source line CSL and the bit line BL in order.

Referring to FIG. 3, in the erase-verifying mode, the ground voltage of 0V is applied to the common source line CSL. The power source voltage of 5V is applied to the ground selection line GSL. The WL erase-verifying voltage Vwevfy of 0V is applied to the word lines WL0˜WL31. The power source voltage VDD of 5V is applied to the string selection line SSL, and the bulk erase-verifying voltage Vbevfy of −1V is applied to bulk 112.

By applying to word lines WL0˜WL31 of the selected memory block the WL erase-verifying voltage Vwevfy (0V), the bit line (e.g., BL0) is conditioned on the ground voltage Vss or a precharged voltage Vprec in accordance with the condition that the memory cells MC0˜MC31 of the string corresponding to the bit line BL0 have been successfully erased. For instance, if the memory cells MC0˜MC31 have all been successfully erased, the bit line BL0 exhibits the ground voltage Vss. Otherwise, at least one of the memory cells MC0˜MC31 in cell string 111 has not been properly erased, and the bit line BL0 is raised to the precharged voltage Vprec by its corresponding page buffer.

In the erase-verify operation, latches (not shown) in page buffer circuit 140 hold voltage levels for corresponding bit lines BL0˜BLm-1. The latched values are transferred to pass/fail detection circuit 150. Pass/fail detection circuit 150 determines whether data values stored in page buffer circuit 140 are the same as the corresponding pass data values. A detected result from pass/fail detection circuit 150 is stored in a state register (not shown) of control logic block 160. The detected result stored in the state register may be output to an external circuit through a state reading operation following completion of the erasing mode. The state-read result may then be used to determine whether the selected memory block has been successfully erased.

Nonvolatile memory device 100 in the foregoing embodiment of the invention is configured to provide a negative voltage to bulk 112 during an erase-verify operation. Supplying the negative voltage to bulk 112 causes an increase in the threshold voltage of the erased memory cells as a group.

FIG. 4 is an equivalent circuit diagram of a unit memory cell 113 and further illustrates the increase in the threshold voltage caused by the application of a negative voltage to the bulk. Referring to FIG. 4, memory cell 113 comprises a gate receiving a gate voltage Vg, a drain receiving a drain voltage V_{D}, a source receiving a source voltage V_{S}, and a bulk receiving a bulk voltage V_{B}. Generally, the relation between the threshold voltage Vth and the bulk voltage V_{B} is given by following Equation 1.

Vₜₕ=Vₜₕ₀+γ(\sqrt{V_{S}−V_{B}+2φ}−\sqrt{φ})

In Equation 1, Vₜₕ₀ is a zero substrate bias voltage, γ is a body effect parameter, and φ is a surface voltage parameter. Referring to Equation 1, if the negative bulk voltage V_{B} is applied to bulk 112, then threshold voltage Vth increases.

FIG. 5 is a graph illustrating the change in a threshold-voltage distribution corresponding to an erased memory cell state as a function of voltage applied to the bulk 112. Referring to FIG. 5, when the bulk erase-verifying voltage Vbevfy is 0V (curve A), weak-erased memory cells (portion C of curve A) cannot be effectively screened despite the fact that an erase-verify operation is performed in relation to an applied WL erase-verifying voltage Vwevfy. In contrast, when an applied bulk erase-verifying voltage Vbevfy is −1V (curve B), the entire threshold-voltage distribution increases. Thus, when an erase-verify operation is performed using a WL erase-verifying voltage Vwevfy, the weak-erased memory cells (portion C′ of curve B) may be effectively screened.

FIG. 6 is a block diagram of a memory system 10 according to an embodiment of the invention. Memory system 10 comprises a nonvolatile memory 100 and a memory controller 200. Nonvolatile memory 100 may be similar to the device shown in FIG. 1. Memory controller 200 operates to control nonvolatile memory 100 and performs erase-verify operations by raising the threshold voltage of the memory cells to a predetermined level. When an erase-verify operation fails, memory controller 200 performed a re-erase operation on the failed memory block or may alternately treat the failed memory block as a bad block, if a number of re-erase operations fail.

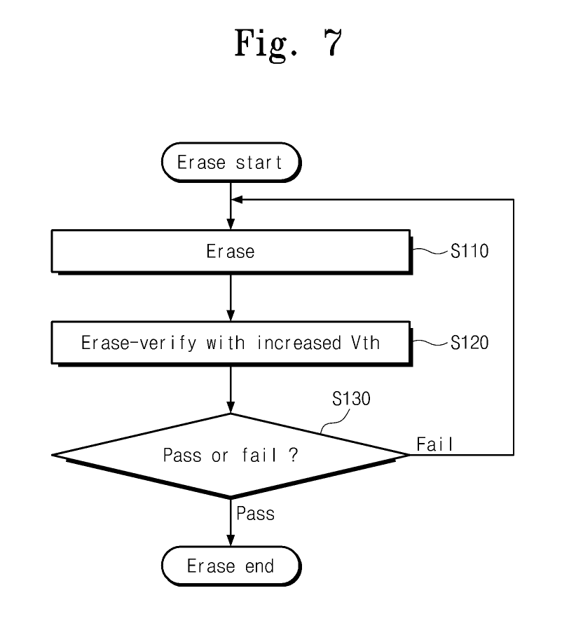

FIG. 7 is a flow chart summarizing an erasing method according to an embodiment of the invention. Referring to FIGS. 1, 6, and 7, the erasing method is carried out as follows. The illustrated erasing method is roughly divided into an erasing step S110 and an erase-verifying step S120, where the erase-verifying step S120 is executed using increased threshold voltages for the memory cells. As illustrated in FIG. 1, nonvolatile memory 100 supplies a negative voltage to bulk 112 in order to increase the threshold voltage of selected memory cells during the erasing mode.

Based on the result of erase-verifying step S120, control logic block 160 determines a pass/fail state and provides a corresponding pass/fail signal P/F to pass/fail detection circuit 150 S130. If the determination result is pass, the selected memory block is regarded as operating normally. To the contrary, if the determination result is fail, memory controller 200 enables the execution of a re-erase operation for nonvolatile memory 100 in an attempt to properly erase weakly erased memory cells in the selected memory block. During this re-erase operation, control logic block 160 of nonvolatile memory 100 may be configured to execute the re-erase operation directed to the selected memory block using an increased erasing voltage.

According to the foregoing erasing method, the erase-verifying operation or mode is performed in relation to an increased threshold voltage for the memory cells in the selected memory block. Therefore, it is able to screen weak-erased memory cells in the selected memory block.

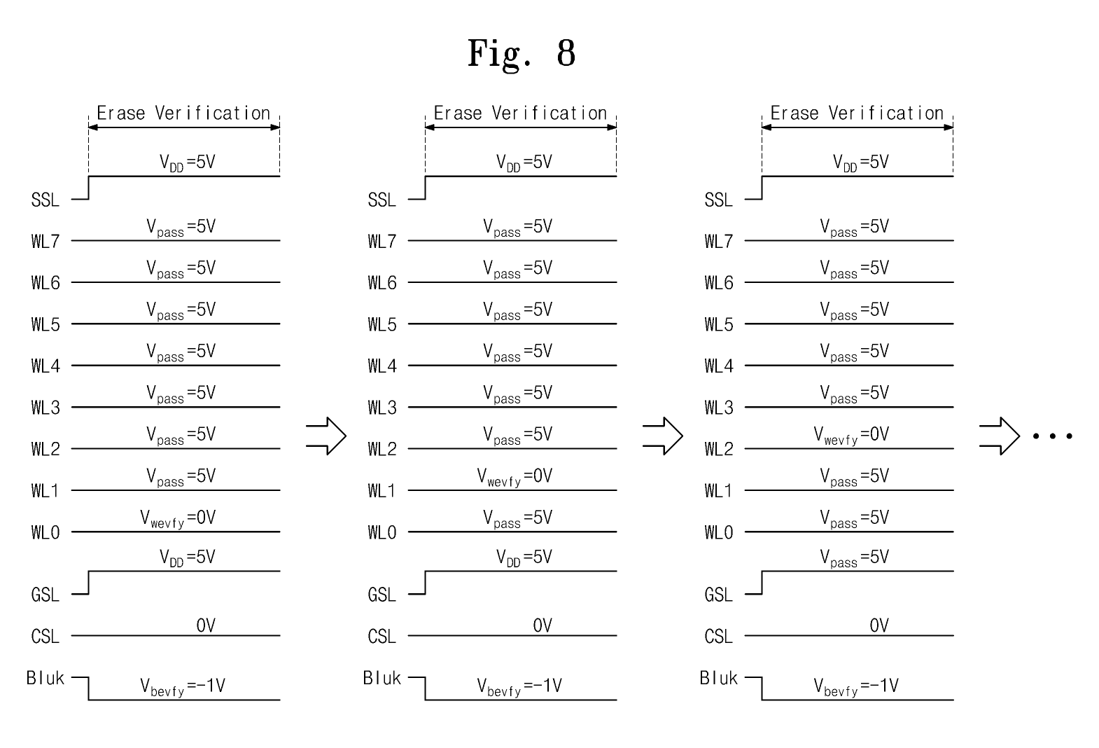

FIG. 8 is a waveform diagram showing other bias conditions for the erase-verify operation according to embodiments of the invention. The erase-verify operation shown in FIG. 8 is performed on a page-by-page (or page unit) basis within the selected memory block. In other words, the WL erase-verifying voltage Vwevfy is sequentially applied to the word lines WL0˜WL31. Referring to FIGS. 1, 6, and 8, voltage generator 130 operates to generate voltages necessary for the following erase-verify operation under the control of control logic block 160. In the erase-verify operation, a memory block is selected in response to a block address and a word line is (e.g., WL0) selected in response to a row address. The power source voltage VDD is applied to the string and ground selection lines SSL and GSL of the selected memory block. The WL erase-verifying voltage Vwevfy is applied to the selected word line WL0 while the passing voltage Vpass is applied to deselected word lines WL1˜WL31. The bulk erase-verifying voltage Vbevfy is applied to the bulk. The bulk erase-verifying voltage Vbevfy is a negative voltage. In the embodiment shown in FIG. 8, for convenience of description, the power source voltage VDD is 5V, the WL erase-verifying voltage Vwevfy is 0V, the passing voltage is 5V, and the bulk erase-verifying voltage is −1V.

As illustrated in FIG. 8, after completing the erase-verifying operation applied to the first selected word line WL0, a next operation is performed relative to the second word line WL1. The erase-verifying operation with the second word line WL1 is similar to that with the first word line WL0, but different from each other in the order of word line. After completing the erase-verifying operation to the second word line WL1, a next erase-verifying operation is conducted in relation to the third word line WL2. In this manner, the erase-verify operation is carried out for all of the word lines WL0˜WL31. Control logic block 160 operates to control voltage generator 130 and page buffer circuit 140 so as to execute the sequential operations of the erase-verify operation for the word lines WL0˜WL31.

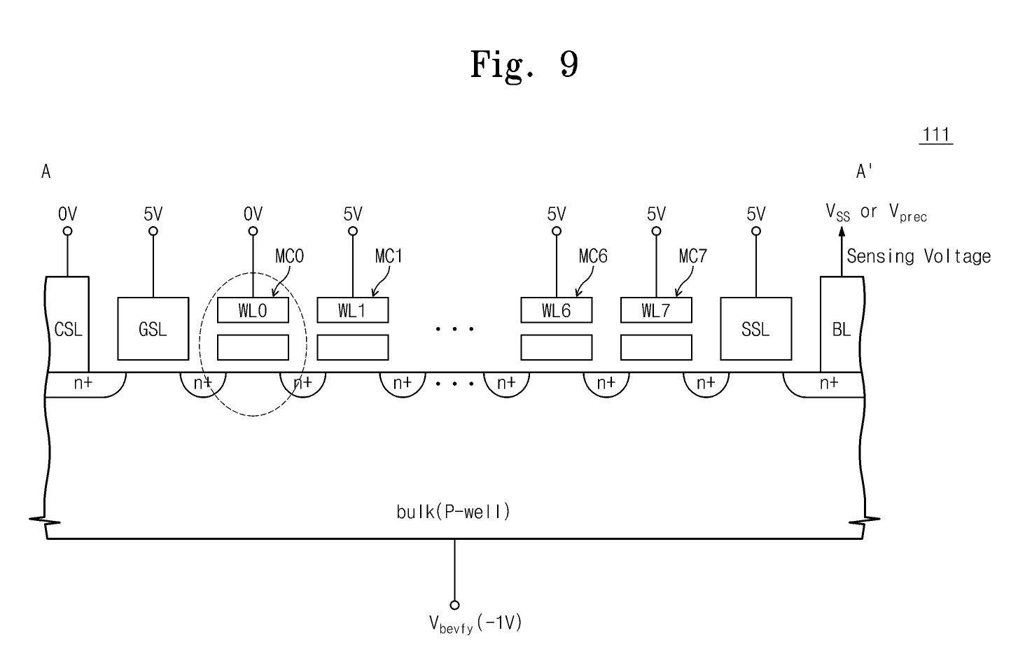

FIG. 9 is a sectional diagram of the string taken along the line A-A′ of FIG. 1, and further structurally illustrates the bias condition of FIG. 8. Referring to FIG. 9, in the erase-verify operation, 0V of the ground voltage Vss is applied to the common source line CSL and 5V of the power source voltage VDD is applied to the ground selection line GSL. 0V of the WL erase-verifying voltage Vwevfy is applied to the first selected word line WL0 while 5V of the passing voltage Vpass is applied to the deselected word lines WL1˜WL31. The power source voltage VDD of 5V is applied to the string selection line SSL and the bulk erase-verifying voltage Vbevfy of −1V is applied to the bulk.

By setting the selected word line WL0 on the WL erase-verifying voltage Vwevfy of 0V, the bit line (e.g., BL0) is conditioned on the ground voltage Vss or the precharged voltage Vprec in accordance with the condition that the memory cells MC0˜MC31 of the string corresponding to the bit line BL0 have been successfully erased. For instance, if the memory cells MC0˜MC31 have been all erased, the bit line BL0 is conditioned in the ground voltage Vss. Otherwise, at least one of the memory cells MC0˜MC31 of cell string 111 has not been erased or is weakly erased, and bit line BL0 rises to the precharged voltage Vprec by operation of its corresponding page buffer.

In the erase-verify operation, latches (not shown) in page buffer circuit 140 hold voltage levels of their corresponding bit lines BL0˜BLm-1. The latched values are transferred to pass/fail detection circuit 150. Pass/fail detection circuit 140 determines whether data stored in page buffer circuit 140 is the same as the pass data. A detected result from pass/fail detection circuit 150 is stored in a state register (not shown) of control logic block 160. The detected result stored in the state register may be output to an external circuit through a state reading operation following an erase operation. The state-read result is finally used in checking whether the selected word line has been successfully erased. Control logic block 160 enables the erase-verify operation by sequentially selecting all of the word lines WL0˜WL31. Meanwhile, control logic block 160 also conducts a count-up operation whenever a fail outcome is determined. This count-up operation allows remedy or properly handling of a bad block in accordance with the number of failed word lines.

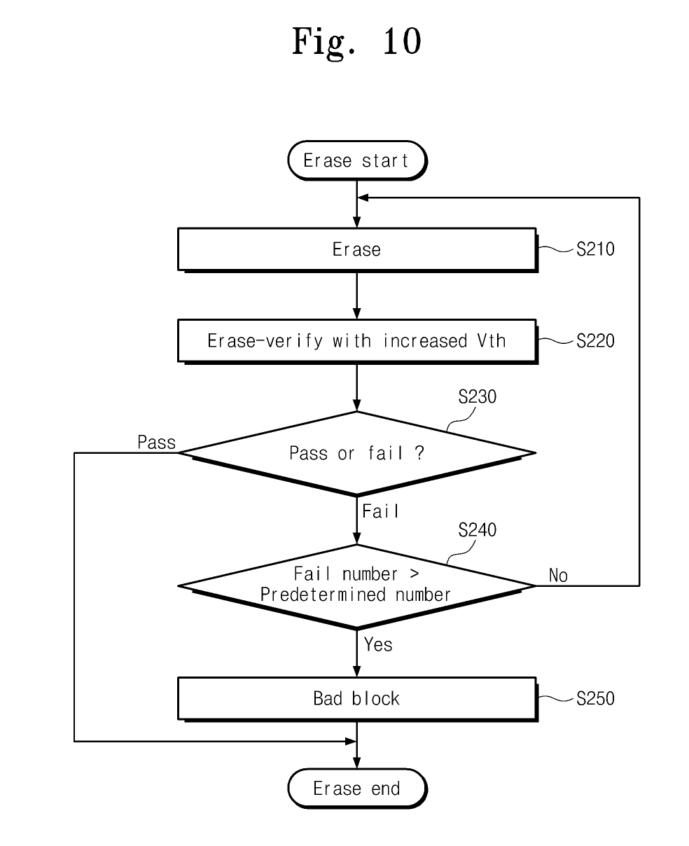

FIG. 10 is a flow chart summarizing another erasing method according to an embodiment of the invention. The erasing method shown in FIG. 10 performs an erase-verify operation on a word line basis as shown in FIG. 8. Referring to FIGS. 1, 6, 8, and 10, the erase-verify operation proceeds as follows. An erasing step S210 is the same as that described in relation to FIG. 1 and an erase-verifying step S220 is the same as that described in relation to FIG. 8. Control logic block 160 conducts the erase-verify operation by word line and stores information, said information denoting a condition of whether the erase-verifying operations with respect to the various word lines have been successfully completed or not. This information may be stored in a state register (not shown).

If the determination results of the erase-verification for the word lines WL0˜WL31 are all “pass”, the selected memory block is deemed completely erased. To the contrary, if the determination results of the erase verification for the word lines WL0˜WL31 sequentially selected include one or more “fails”, control logic block 160 counts up the number of fails and stores the counted result in an additional register (not shown) (S230). Completing the erase-verification for all of the word lines WL0˜WL31, the number of fails stored in the register may be the number of word lines experience a failure during the erase operation. After completing the erase-verification for all of the word lines WL0˜WL31, control logic block 160 determines whether the number of fails is larger than a reference value (S240). From this determination, if the number of fails is larger than the reference value, control logic block 160 generates a “bad-block” indication signal and provides this signal to memory controller 200 which may use one or more conventional techniques for repairing or handling the bad block indication (S250). For example, memory controller 200 may change mapping information to treat a corresponding memory block (e.g., a block containing weak-erased memory cells) as a bad block in response to the bad-block processing signal received from control logic block 160. Thereafter, it terminates the procedure of erasing the selected memory block.

In the erasing method according to embodiments of the invention, a selected memory block is treated as a bad block when the number of fail word lines detected after the erase-verification is over a predetermined or reference value. Thereby, programming failures that might otherwise fail because they are directed to weak-erased memory cells may be avoided.

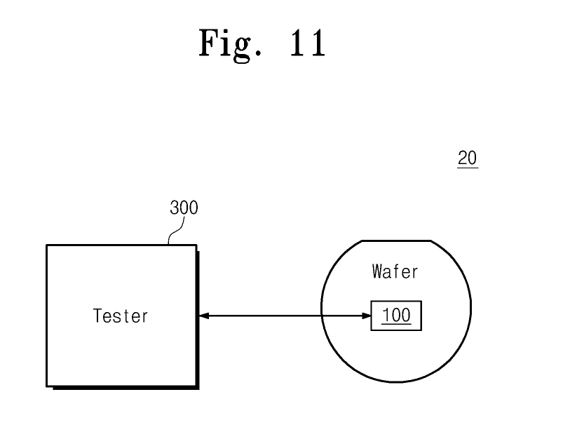

The erase-verify operation according to embodiments of the invention may be performed during wafer-level testing. FIG. 11 is a general block diagram of a test system 20 according to an embodiment of the invention. Referring to FIG. 11, test system 11 comprises of a wafer-level nonvolatile memory chip 100, and a tester 300 for testing wafer-level nonvolatile memory chip 100. Tester 300 functions in an erase-testing mode in relation to nonvolatile memory chip 100 by use of an erase-verify operation according to an embodiment of the invention. Here, wafer-level nonvolatile memory chip 100 may include circuitry that is substantially the same as that shown in FIG. 1.

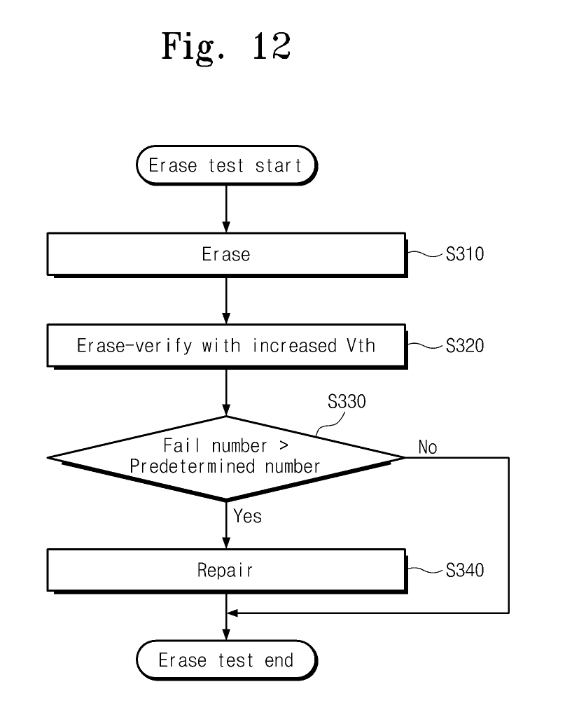

FIG. 12 is a flow chart summarizing an erase-testing mode using an erase-verify operation according to an embodiment of the invention. Referring to FIGS. 11 and 12, the erase-verify operation proceeds as follows. First, an erasing operation is carried out in relation to a selected memory block (S310). After the erasing operation, an erase-verifying operation is carried out for each word line in the selected memory block using an increasing threshold voltage for the constituent memory cells (S320). From a corresponding erase-verification operation, it is determined whether or not a number of failed word lines is larger than a reference value (S330). If the number of failed word lines is larger than the reference value, tester 300 executes a repair operation in relation to the selected memory block of nonvolatile memory chip 100 (S340). For example, the failed word lines of the selected memory block may be replaced using redundant word lines. The erase-testing mode may be accomplished in certain embodiments of the invention using an electrical die sorting (EDS) process.

The nonvolatile memory device according to embodiments of the invention operates with a negative voltage applied to the bulk during the erase-verify operation. The negative bulk voltage causes the threshold voltage of the selected memory cells to increase. Under this condition, the erase-verify operation is executed to effectively screen weak-erased memory cells. A memory block including weak-erase memory cells having an increased threshold voltage may be detected during the erase-verification operation and treated as a bad block or repaired. As a result, the nonvolatile memory device enjoys improved overall reliability for the all memory blocks.

A nonvolatile memory device according to an embodiment of the invention may be variously incorporated within a flash memory device, a flash memory sub-system, or a flash memory system.

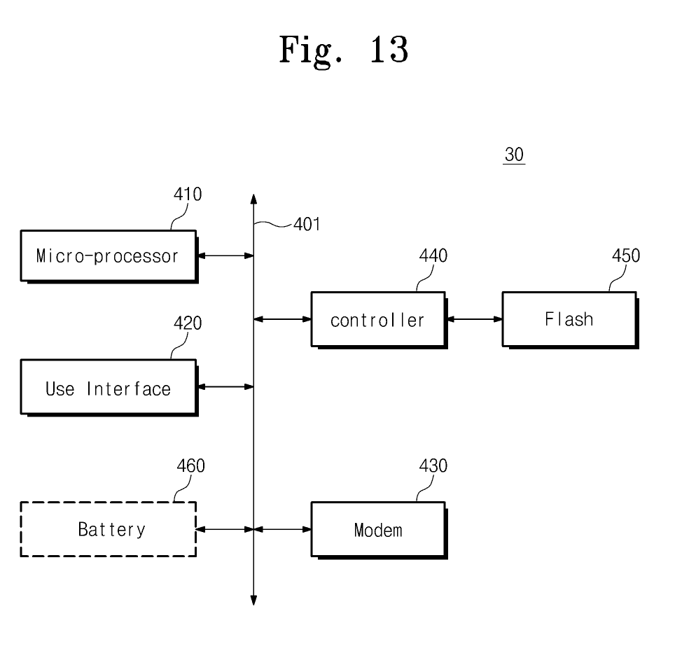

A schematic organization for a general computational logic platform comprising 30, including a flash memory device according to an embodiment of the invention is illustrated in FIG. 13. In the illustrated example, computational logic platform 30 includes a microprocessor 410, a user interface 420, a modem 430 such as a baseband chipset, a flash memory controller 440, and the flash memory device 450, all of which are connected to a bus 401. Flash memory device 450 may be configured like the nonvolatile memory device shown in FIG. 1. Flash memory device 450 may receive, store and provide n-bit data in relation to microprocessor 400 using memory controller 440.

Where computational logic platform 30 is a mobile apparatus, it may further include a battery 460 supplying power. Although not shown in FIG. 13, computational logic platform 30 may further include an application specific chipset, a camera image processor (e.g., CMOS image sensor; CIS), a mobile DRAM, etc. The memory controller and flash memory device may constitute a solid state drive or disk using a nonvolatile type as a memory for storing data.

Flash memory device 450 and/or memory controller 440, according to an embodiment of the invention may be mounted on the system by means of various packaging. For instance, flash memory device 450 and/or memory controller 440 may be packaged using one of many different types of packages, e.g., Package-on-Package (PoP), Ball Grid Arrays (BGAs), Chip Scale Packages (CSPs), Plastic Leaded Chip Carrier (PLCC), Plastic Dual In-line Package (PDIP), Die in Waffle Pack, Die in Wafer Form, Chip-On-Board (COB), CERamic Dual In-line Package (CERDIP), Plastic Metric Quad Flat Pack (MQFP), Thin Quad Flat Pack (TQFP), Small Outline (SOIC), Shrink Small Outline Package (SSOP), Thin Small Outline (TSOP), Thin Quad Flat Pack (TQFP), System In Package (SIP), Multi-Chip Package (MCP), Wafer-level Fabricated Package (WFP), Wafer-level Processed Stack Package (WSP), or Wafer-level Processed Package (WSP).

The above-disclosed subject matter is to be considered illustrative, and not restrictive, and the appended claims are intended to cover all such modifications, enhancements, and other embodiments, which fall within the scope of the invention. Thus, to the maximum extent allowed by law, the scope of the present invention is to be determined by the broadest permissible interpretation of the following claims and their equivalents, and shall not be restricted or limited to only the foregoing detailed description.

What is claimed is:

1. An erasing method for a nonvolatile memory device, the method comprising:
erasing selected memory cells; and
erase-verifying the selected memory cells under a bias condition that increases the threshold voltage of the selected memory cells.

2. The method of claim 1, wherein erase-verifying the selected memory cells comprises:
providing a negative voltage to a bulk in which the selected memory cells are fabricated to increase the threshold voltage of the selected memory cells.

3. The method of claim 1, further comprising:
repeatedly erasing and erase-verifying the selected memory cells if one or more of the selected memory cells fail erase-verifying.

4. The method of claim 1, wherein erasing and erase-verifying are performed on a memory block by memory block basis.

5. The method of claim 1, wherein erasing the selected memory cells is performed on a memory block by memory block basis, and the erase-verifying is sequentially performed on a page by page basis within a selected memory block.

6. The method of claim 5, further comprising:
storing a number of failed pages identified during the erase-verifying.

7. The method of claim 6, further comprising:
handling the selected memory block as a bad block if the number of failed pages in the selected memory block exceeds a reference value.

8. An erase-testing method for a nonvolatile memory device, the method comprising:
erasing selected memory cells;
erase-verifying the selected memory cells under a bias condition that increases the threshold voltage of the selected memory cells;
identifying a number of failed word lines in the selected memory block in accordance with the erase-verifying of the selected memory cells; and
repairing one or more of the failed word lines, if the number of failed word lines exceeds a reference value.

9. The method of claim 8, wherein erase-verifying the selected memory cells comprises:
providing a negative voltage to a bulk in which the selected memory cells are fabricated to increase the threshold voltage of the selected memory cells.

10. The method of claim 8, wherein erasing the selected memory cells is performed on a memory block by memory block basis, and the erase-verifying is sequentially performed on a page by page basis within a selected memory block.

11. The method of claim 8, wherein the erase-testing method is part of an electrical die sorting process.

12. A nonvolatile memory device comprising:
a plurality of nonvolatile memory cells arranged in a matrix of word lines and bit lines;
a voltage generator configured to generate a word-line erase-verifying voltage applied to the word lines, and a bulk erase-verifying voltage applied to a bulk in which the plurality of memory cells is fabricated;
a page buffer circuit configured to sense erased states for selected memory cells within the plurality of memory cells through the bit lines during an erase-verify operation; and
a control logic block configured to control an erase operation, control the voltage generator such that the bulk erase-verifying voltage is a negative voltage increasing the threshold voltage of the selected memory cells during the erase-verify operation, and to determine whether the selected memory cells have been successfully erased in relation to the erased states of the selected memory cells as sensed by the page buffer circuit following the erase-verify operation.

13. The nonvolatile memory device of claim 12, wherein the control logic block is further configured to execute a re-erase operation when a fail result is determined during the erase-verify operation.

14. The nonvolatile memory device of claim 12, wherein the erase operation and the erase-verifying operation are performed on a memory block by memory block basis.

15. The nonvolatile memory device of claim 12, wherein the erase operation is performed on a memory block by memory block basis, and the erase-verifying operation is sequentially performed on a page by page basis within a selected memory block.

16. The nonvolatile memory device of claim 15, further comprising:
a register storing a number of failed word lines detected during the erase-verifying operation.

17. The nonvolatile memory device of claim 16, wherein the control logic block is further configured to determined whether the stored number of the failed word lines exceeds a reference value, and if the failed word lines exceeds the reference value, treating the selected memory block as a bad block.

18. The nonvolatile memory device of claim 12, wherein the nonvolatile memory device is a NAND flash memory.

19. The nonvolatile memory device of claim 18, wherein the NAND flash memory is an embedded NAND flash memory device.
